(19) United States
(12) Patent Application Publication
(10) Pub. No.: US 2003/0168004 A1
(43) Pub. Date: Sep. 11, 2003

(54) Manufacturing apparatus of an insulation film

(76) Inventors: Yukihiko Nakata, Nara-shi (JP); Kazufumi Azuma, Yokohama-shi (JP); Tetsuya Okamoto, Kamakura-shi (JP); Masashi Goto, Yokohama-shi (JP)

Correspondence Address: GRAYBEAL, JACKSON, HALEY LLP, 155 - 108TH AVENUE NE, SUITE 350, BELLEVUE, WA, 98004-5901, US

(21) Appl. No.: 10/356,721

(22) Filed: Jan. 30, 2003

(30) Foreign Application Priority Data
Jan. 31, 2002 (JP) 2002-23077

(51) Int. Cl. C23C 14/00

(52) U.S. Cl. 118/50.1

(57) ABSTRACT

The invention provides apparatus for forming an insulating film which is able to reduce the decrease in the light amount due to the light transmittable window, to process the large scale base plate, and to improve the oxidation speed.

In apparatus for forming an insulating film on a semiconductor surface by oxidizing the surface of the semiconductor as a substrate 6 by means of oxygen atom active species generated when irradiating a N₂+O₂ mixed gas 10 including at least oxygen with the light emitted from a xenon excimer lamp 1, wherein there are provided a gas intake port 8 and a gas exhaust port 9, by both of which the pressure of the atmosphere in the light source portion 2 sealed with a nitrogen gas 3 absorbing no light from the xenon excimer lamp 1 at an atmospheric pressure is kept approximately equal to the pressure of the N₂+O₂ mixed gas 10 surrounding the surface portion of the substrate 6.

### CROSS-REFERENCE TO A RELATED APPLICATION

The present application claims priority from Japanese patent application No. 2002-23077, filed 31 Jan. 2002, which is incorporated by reference.

### BACKGROUND OF THE INVENTION

1. Field of the Invention

The present invention relates to apparatus for forming an insulating film on a semiconductor surface by oxidizing the above surface by using oxygen atom active species as generated when an atmosphere including at least oxygen is irradiated with the light emitted from a light source.

2. Prior Art

For instance, in order to form a combination structure made up of the semiconductor and the insulating film, which is used by a field effect transistor (FET) having a metal oxide semiconductor (OMS) structure, a polycrystalline-silicon thin-film transistor and so forth, an insulating film is formed on the semiconductor.

The FET is widely used in a large scale integrated circuit (LSI). In this case, however, in order to further improve the high performance of the LSI, there are demanded the thinner and better quality insulating film capable of being formed at a lower temperature as well as a better characteristic of the boundary formed between the semiconductor and the insulating film.

When forming the insulating film on the single-crystalline silicon surface, the thermal oxidation method has been used as the most popular and common method for forming the insulating film thus far. In this method, the single-crystalline silicon is heat treated in a temperature range of 700° C. through 1000° C. In this case, the oxidation reaction proceeds toward the inside of the semiconductor. As a result, the boundary between the semiconductor and the insulating film (gate insulating film for instance) made of an oxidized silicon film generated by the above heat-treatment comes to be formed inside the original semiconductor. Thus, the above prior method includes a good point that the resultant boundary has such a very good quality that is hardly influenced by the surface state of the original semiconductor.

According to the above method for forming the insulating film, however, it is apt to takes place that the silicon wafer is warped through the high temperature heat treatment. If the low temperature heat treatment is carried out, however, the issue of the wafer warp might be solved to some extent, but the oxidation speed is rapidly dropped. Accordingly, this is undesirable from the practical standpoint. Also, there has been reported the formation of an insulating film by means of plasma chemical vapor deposition (CVD), but it seems hard to obtain a good boundary characteristic. The most significant issue in this plasma CVD method is that the insulating film being processed can not be prevented from the damage caused by the plasma ion.

On one hand, in the field of the liquid crystal display (LCD), with the recent improvement and advance of the display in its size, the number and pitch of pixels, function and performance, and so forth, a severe demand for precise and reliable minute thin film transistors (TFT) is becoming stronger day by day and year by year. Reflecting such a situation, the need for a TFT using a polycrystalline silicon (Poly-Si) film is enhanced on behalf of the need for a prior art TFT using amorphous silicon film. So far, a gate insulating film, which gives a large influence over the performance and reliability, has been formed by means of the plasma CVD method. As described above, however, if the gate insulating film is grown by means of the plasma CVD, it is hardly possible to avoid the damage due to the plasma. Especially, it becomes impossible to precisely control the threshold voltage of the transistor, which results in throwing an undesirable problem on the reliability of the transistor. For instance, if a SiO₂ film is formed by the plasma CVD with a mixed gas consisting of tetra ethyl ortho silicate (TEOS) and O₂, a finished SiO₂ film comes to include carbon contained in the above mixed gas. In this case, even if the SiO₂ film formation is executed at a temperature of about 350° C. or more, it becomes so hard to reduce the carbon concentration to the level of 1.1×10²⁰ atoms/cm³ or less. Especially, if setting the film formation temperature to be about 200° C., the carbon concentration in the finished film becomes 1.1×10²¹ atoms/cm³. In orther words, the carbon concentration is increased by one digit so that it is very difficult to reduce the film formation temperature.

Also, in case of the film formation by means of the plasma CVD method using the mixed gas system consisting of SiN₄ and N₂O, as the nitrogen concentration in the boundary portion indicates a very high value such as 1 atom % or more, it is impossible to reduce the fixed electric charge density to the value of 5×10¹¹cm⁻² or less. Thus, it is impossible to use the produced film as the gate insulating film.

Furthermore, an electron cyclotron resonance (ECR) plasma CVD method and an oxidation method using oxygen plasma have been developed as a method which makes it possible to decrease the ion damage caused by the plasma CVD method and to produce a high quality insulating film and as well. However, as far as plasma is generated and used in the vicinity of the semiconductor surface, it is very difficult to perfectly solve the ion damage problem.

Still further, according to the disclosure by the Japanese Patent Public Disclosure No. 4-326731, for instance, there has been proposed an oxidation method which carries out oxidation in the atmosphere including ozone. According to this method, ozone is first optically generated and the generated ozone is then optically resolved into oxygen atom active species. Like this, as this method has to execute a two-step reaction, it is inferior in not only efficiency but also reaction speed.

On one hand, there is a report on a research reporting that silicon is oxidized at such a low temperature as 250° C. by using an excimer lamp (J. Zhang et al., A. P. L., 71(20), 1997, P2964).

Still further, there is another report on a film formation method. In this method, an atmosphere including oxygen gas is irradiated by the light emitted from a xenon excimer lamp to generate oxygen atom active species, which oxidize the semiconductor surface to form the first layer of the insulating film thereon. After forming the first layer of the insulating film on the semiconductor surface, the second layer of the insulating film is formed by means of the plasma CVD method using a mixed gas of TEOS and O₂ or a mixed gas of SiH₄ and N₂O.

Besides the patent disclosure and research reports as described above, there are research reports relating to the insulating film formation. Some are enumerated below for reference:

1) Y. Nakata, T. Hamada, T. Hamada, T Igota and Y. Ishii: Proceedings of Int. Conf. on Rapid Thermal Processing for Future Semiconductor Devices (2001)

2) Y. Nakata, T. Okamoto, T. Hamada, T. Itoga and Y. Ishii: Proceedings of Int. Workshop on gate Insulator 2001 (2001)

3) Y. Nakata, T. Okamoto, T. Hamada, T. Itoga and Y. Ishii: Proceedings of Asia Display/IDW′ 01 p.375 (2001)

4) Y. Nakata, T. Itoga and Y. Ishii: 2001 Spring 48th JSAP annual meeting (Tokyo) held by The Japan Society of Applied Physics.

A method for producing oxygen atom active species by using light rays has such a good point that an excellent boundary face can be formed without receiving any ion damage. However, a device for executing the optical oxidation still holds such problems to be solved as described in the following.

FIG. 8 is a schematic sectional view of a prior art apparatus for forming an insulating film using optical oxidation. In this figure, a reference numeral 801 indicates a xenon excimer lamp as a light source, 802 a light source portion (lamp house), 803 N₂ gas sealed in the light source portion 802 approximately at the atmospheric pressure, 804 a light passable window made of synthesized quartz, 805 a vacuum reaction chamber (vacuum chamber), 806 a substrate, 807 a substrate supporting base, and 808 vacuum state.

In this prior art apparatus as shown in FIG. 8, the light having a wavelength of 172 nm comes in the reaction chamber 805 where the substrate 806 is mounted on and held by the substrate supporting base 807, and the semiconductor surface on the substrate 806 is oxidized to form an insulating film thereon.

If the light emitted from the xenon excimer lamp 802 has a short wavelength and comes out in the air, it resolves oxygen in the air into oxygen atom active species and is soon absorbed in the air phase having thickness of several millimeters. Therefore, the light source portion (lamp house) 802 having the light transmittable window 804 usually made of synthesized quartz is fully filled with nitrogen gas 803 absorbing no light having the wavelength of 172 nm, approximately at the atmospheric pressure, thereby avoiding the light absorption by the air. Furthermore, in order to reduce impurities mixed with the insulating film to be formed, there is evacuated the inside of the reaction chamber 805 in which the substrate 806 to be oxidized is set. Then, oxygen gas is introduced to the evacuated reaction chamber and is kept at a desired pressure. The oxygen gas in the reaction chamber is irradiated and resolved into oxygen atom active species by the light coming in through the light transmittable window 804. The surface of the semiconductor is oxidized by the oxygen atom active species, thereby the insulating film being formed.

In this case, the light transmittable window 804 receives a gas pressure of about 1 kg/cm² which is equal to a gas pressure difference between a the atmospheric pressure and the pressure nearly equal to the vacuum pressure in the reaction chamber. Accordingly, the light transmittable window 804 has to have a thickness capable of withstanding such pressure difference.

As shown in the following table 1, for instance, in case of the window 804 having a size of 300 through 250 square mm, it has to have a thickness of at least about 30 mm.

TABLE 1
Wavelength of light 172 nm

| | | | | | | | | |
|---|---|---|---|---|---|---|---|---|
| Window | 6 | inch φ | 300 | mm φ | 250 | mm sq. | 300 | mm sq. |
| Size | | | | | | | | |
| Quartz | 4.3 | mm | 30 | mm | 30.6 | mm | 30.8 | mm |
| Thick | | | | | | | | |

| | | | | |
|---|---|---|---|---|
| Transmit- | 45% | 30% | 30% | 25.6% |
| tance | | | | |

FIG. 9 is a graph showing the relation between the light transmittance (%) of the synthesized quartz plate and the light wavelength (nm), when taking the thickness (1 mm, 10 mm, 30 mm) of the synthesized quartz plate as a parameter.

As will be seen from the graph shown as FIG. 9, however, the light transmittance of the synthesized quartz plate to the light having the wavelength of 172 nm is rapidly dropped according to the increase of the synthesized quartz plate thickness. When the thickness is 30 mm, light transmittance is reduced to about 30%, in other words, this means that the usable light becomes only ⅓ and the oxidation speed is dropped to a great extent. This is a problem still held by the prior art apparatus as has been described in the above. This problem would become more serious if considering a practical large scale apparatus of this kind for handling a large scale substrate of 1 meter square, for instance. The light transmittable window has to be made of the synthesized quart having an unpractical thickness.

Accordingly, an object of the invention is to provide apparatus for manufacturing an insulating film, which makes it possible to enlarge the scale of a substrate to be processed and to increase oxidation speed.

### SUMMARY OF THE INVENTION

In order to solve the problems as described above, there is provided apparatus for forming an insulating film having the constitution that is recited in the scope of claims for patent as per attached to this specification.

That is, according to the recitation of claim 1, there is provided apparatus for forming an insulating film on a semiconductor surface by oxidizing the above surface by using oxygen atom active species which are generated when irradiating an atmosphere including at least oxygen with the light emitted from a light source, wherein there is provided a means for keeping the pressure of the atmosphere surrounding the light source and that of the atmosphere surrounding the semiconductor surface portion approximately equal to each other.

In the apparatus as recited in claim 1, as the pressure of the atmosphere surrounding the light source and that of the atmosphere surrounding the semiconductor surface portion are kept approximately equal to each other, it becomes possible to make the light transmittable window thinner. With this, it becomes also possible to reduce the decrease in the light amount due to the window small, to enlarge the size of the substrate to be processed, and to improve the oxidation speed.

Furthermore, according to the recitation of claim 2, in the apparatus for forming an insulating film as recited in claim 1, there is provided a light transmittable window allowing the light emitted from the light source to pass it through between the light source and the semiconductor surface portion, the pressure of the atmosphere surrounding the light source is made to be at an atmospheric pressure by a gas not absorbing the light emitted from the light source, and also there is provided a means for making the pressure of the atmosphere surrounding the semiconductor surface to be at the atmospheric pressure by a mixed gas including at least oxygen and the gas not absorbing the light emitted from the light source. Accordingly, there is no need for the apparatus recited in claim 2 to have a pressure isolation wall.

Still further, according to the recitation of claim 3, in the apparatus for forming an insulating film as recited in claim 2, the atmosphere surrounding the semiconductor surface portion communicates with the outdoor air and the pressure is kept at an atmospheric pressure by using the mixed gas. Accordingly, there is no need for the apparatus recited in claim 3 to have a pressure isolation wall.

Still further, according to the recitation of claim 4, in the apparatus for forming an insulating film as recited in claim 1, there is provided a means for transferring a plurality of substrates to pass them under the the light source. Accordingly, the apparatus according to claim 4 is able to improve the throughput.

Still further, according to the recitation of claim 5, in the apparatus for forming an insulating film as recited in claim 1, there are provided a means for reducing both pressures of atmospheres surrounding the light source and the semiconductor surface without making difference pressures between them, and a means for returning both pressures of atmospheres surrounding the light source and the semiconductor surface to the atmospheric pressure without making difference pressures between them. As the pressure of the above atmospheres is reduced, the impurities are prevented from being mixed with the substrate.

Still further, according to the recitation of claim 6, in the apparatus for forming an insulating film as recited in claim 5, there is provided a transparent plate between the light source and the semiconductor surface, said transparent plate is held not so as to make any pressure difference between the both atmospheres surrounding the light source and the semiconductor surface.

The apparatus for forming an insulating film as recited in claim 6 is able to prevent the impurities generated by the light source from being mixed with the substrate by means of a transparent plate.

Still further, according to recitation of claim 7, in the apparatus for forming an insulating film as recited in claim 1, the light source is formed by a low-pressure mercury lamp. As the apparatus according to claim 7 uses the low-pressure mercury lamp, the power consumption becomes small.

Still further, according to recitation of claim 8, in the apparatus for forming an insulating film as recited in claim 1, the light source is formed by a xenon excimer lamp. As the apparatus according to claim 8 uses the very efficient xenon excimer lamp, the oxidation speed is made faster, thus the throughput being improved.

Still further, according to recitation of claim 8, in the apparatus for forming an insulating film as recited in claim 1, there are provide a plurality of reaction chambers including a reaction chamber for forming the first insulating film by making the pressure of the atmosphere surrounding the light source and that of the atmosphere surrounding the semiconductor surface portion approximately equal to each other and the second reaction chamber forming the second insulating film on the first insulating film by a deposition method, and a means for transferring the substrate between the plural reaction chambers without exposing the substrate to the outdoor air. According to the apparatus for forming an insulating film recited in claim 9, it is possible to continuously carry out various manufacturing steps such as optical cleaning step, optical oxidation step, annealing step for improving the boundary characteristic, film forming step by the deposition method, and so forth in the vacuum without dropping the productivity.

### BRIEF DESCRIPTION OF THE DRAWINGS

In the accompanying drawings:

FIG. 1 is a schematic sectional view of apparatus for manufacturing an insulating film according to the first embodiment of the invention.

FIG. 2 is a schematic sectional view of apparatus for manufacturing an insulating film according to the second embodiment of the invention.

FIG. 3 is a schematic sectional view of apparatus for manufacturing an insulating film according to the third embodiment of the invention.

FIG. 4 is a schematic sectional view of apparatus for manufacturing an insulating film according to the fourth embodiment of the invention.

FIG. 5 is a flowchart showing a manufacturing process of a polycrystalline silicon thin film transistor (Poly-Si TFT), to which the invention is applicable.

FIGS. 6(a) through 6(e) are sectional views of each element (Poly-Si TFT) obtained at each process of the flowchart as shown in FIG. 5.

FIG. 7 is a schematic sectional view of apparatus for manufacturing an insulating film according to the fifth embodiment of the invention.

FIG. 8 is a schematic sectional view of a prior art apparatus for manufacturing an insulating film by using optical oxidation method

FIG. 9 is a graph showing how the light transmittance of a synthesized quartz plate depends on wavelength of the light.

### DETAILED DESCRIPTION OF THE PREFERRED EMBODIMENTS

The invention will now be described in detail with reference to the accompanying drawings, wherein constituents of the invention having like function and structure will be denoted with like reference numerals and characters in order to avoid the redundant repetitive description.

(First Embodiment)

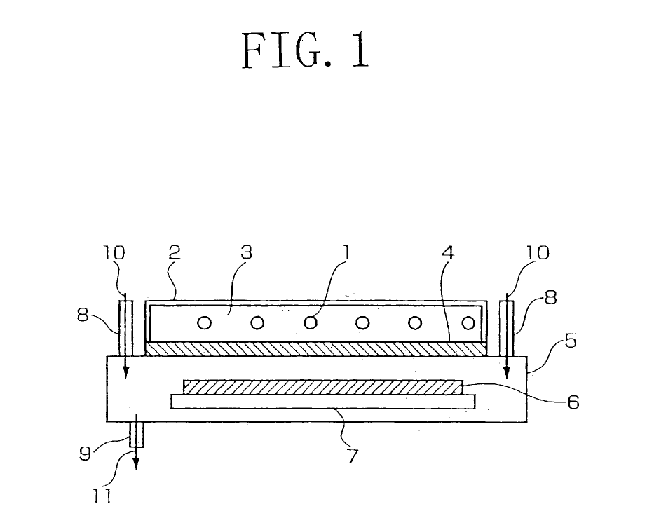

Referring to FIG. 1, a reference numeral 1 indicates a xenon excimer lamp as a light source emitting the light having a wavelength of 172 nm, 2 a light source portion (lamp house), 3 nitrogen gas (N₂ gas) sealed in the light source portion 2 approximately at the atmospheric pressure, 4 a light transmittable window made of synthesized quartz, 5 a reaction chamber, 6 a substrate, 7 a substrate supporting base, 8 a gas intake port, 9 a gas exhaust port, 10 a mixed gas (N₂+O₂ in this instance) approximately at the atmospheric pressure, and 11 is air. In this first embodiment, the substrate 6 is made of single crystalline silicon.

In apparatus for manufacturing an insulating film according to the first embodiment, wherein the semiconductor surface of the substrate 6 is oxidized by oxygen atom active species generated by irradiating the atmosphere containing at least oxygen (N₂+O₂ mixed gas, for instance) by the light emitted from the xenon excimer lamp 1, there is provided a pressure control means for keeping the pressures of the atmosphere in the light source portion 2 (for instance, nitrogen gas 3 sealed in the light source portion 2 but absorbing no light from the xenon excimer lamp 1) and the pressure of the atmosphere surrounding the surface portion of the substrate 6 (i.e. N₂+O₂ mixed gas 10) approximately at the same level, the pressure control means being made up of the gas intake port 8 for introducing the mixed gas (N₂+O₂) 10 approximately at the atmospheric pressure and the gas exhaust port 9 for exhausting the air 11.

Furthermore, in the apparatus according to the first embodiment, there is provide between the light source portion 2 and the surface portion of the substrate 6 the light transmittable window 4 allowing the light from the xenon excimer lamp 1 to pass therethrough. The atmosphere in the light source portion 2 is consisted of nitrogen gas 3 absorbing no light from the xenon excimer lamp 1 is kept at the atmospheric pressure. Still further, there is provided means (gas intake port 8 and the gas exhaust port 9) for keeping the atmosphere surrounding the surface portion of the substrate 6 at the atmospheric pressure by using a mixed gas containing oxygen and a gas not absorbing the light from the xenon excimer lamp 1.

To begin with, after cleaning a circular shaped single crystalline silicon substrate 6, of which the type is P, the crystal orientation (100), and the diameter 6 inches, the substrate 6 is transferred to the optical oxidation chamber, that is the reaction chamber 5 and is set on the substrate supporting base 7 heated at 300° C. by a heater to keep the temperature of the substrate 6 at 300° C.

In the next, the mixed gas 10 consisting of oxygen gas of 5 sccm and nitrogen gas of 760 sccm is supplied to the reaction chamber 5 from the gas intake port 8 through the gas mixing box to expel the air 11 staying inside the reaction chamber 5 through the gas exhaust port 9. It took about 10 minutes to completely replacing the air 11 by the mixed gas 10.

After this, the mixed gas 10 is irradiated by the light having the wavelength of 172 nm by which the oxygen gas is directly and effectively resolved, thereby very active oxygen atom active species being generated. In this case, the partial pressure of the oxygen gas becomes 70 Pa. The (100) plane of the substrate 6 is oxidized with the oxygen atom active species, and the silicon dioxide film (SiO₂ film) grew up to the thickness of about 4.3 nm for 90 minutes by the optical oxidation. The strength of the light used in the first embodiment was 11 mW/cm² at the place on which the substrate 6 is mounted. The distance between the light transmittable window 4 and the substrate 6 was set to be 5 m. The throughput can be improved by using the xenon excimer lamp 1 as the light source.

In the next, in order to facilitate the measurement of the level of the boundary face between the semiconductor and the insulating film by eliminating the tunnel current, the second insulating film (SiO₂ film) having a thickness of about 94 nm was additionally formed to overlap the silicon dioxide film as already formed and existing on the substrate 6, by using the other CVE apparatus using SiH4 gas and N₂O gas. After this, an aluminum film is formed to overlap the second insulating film (SiO₂ film) already formed on the (100) plane of the substrate 6 by using the spattering method. Furthermore, a lot of circular dot patterns with a diameter of 8 nm, made of aluminum film are made by using the photolithographic method. These circular dot patterns are used as test pieces for measuring an electric capacitance. From the measurement of the electric capacitance-voltage characteristic of the test piece, it is found that the fixed electric charge density at the boundary between the substrate and the insulating film is 1×10¹¹/cm² and this value is equivalent to the value of the thermal oxide film (SiO₂ film) obtained by applying the thermal oxidation to the (100) plane of the substrate 6.

According to the first embodiment using the xenon excimer lamp 1 in the reaction chamber (optical oxidation chamber) 5, as shown by the following reaction formula, the oxygen atom active species O(¹D) can be efficiently formed directly from oxygen. This O(¹D) oxidizes the surface ((100) plane of the substrate) of the semiconductor. Like this, in case of using the xenon lamp 1, ozone is not involved in the reaction.

On one hand, in case of using a low pressure-mercury vapor lamp, as shown in the following reaction formula (2), the light with the wavelength of 185 nm produces ozone from oxygen, which produces oxygen atom active species O(¹D) when it is irradiated by the light with a wavelength of 254 nm. That is, the reaction of two steps is required.

Comparing with the low pressure mercury vapor lamp, as the xenon excimer lamp 1 requires only one step reaction, the oxygen atom active species O(¹D can be very efficiently generated, thus the oxidation speed becoming faster. The reaction as shown by the following reaction formula (1) takes place when using the light with a wavelength of 175 nm or less.

Reaction using the xenon excimer lamp:

O₂+hν O(³P)+O(¹P) (Wavelength 172 nm) (1)

Reaction using the low pressure-mercury vapor lamp:

O₂+O(³P)+M O₃+M (Wavelength 185 nm) (2)

O₃+hν O(¹P)+O₂ (Wavelength 254 nm) (3)

Where

O(³P): Oxygen atom in the excited state of ³P level

O(¹D): Oxygen atom in the excited state of ¹D level

M: Oxygen compounds other than O₂, O(³P), and O₃

h: Plank constant

ν: Light wavelength

There are two modes in oxidation process, one is “reaction controlling” mode in which the oxidation speed is determined based on the reaction speed of silicon and oxygen and the other is “diffusion controlling” mode in which the oxidation speed is determined based on such a speed that the oxidation species takes while it diffuses through the silicon dioxide film to reach the boundary between the silicon dioxide (SiO₂) film and the bulk silicon. As the substrate temperature rises, the reaction speed of silicon and oxygen goes up, especially there becomes large the diffusion speed of the oxidation species while it diffuses through the oxide film. Accordingly, it had better to rise the substrate temperature for improving the oxidation speed. Taking account of the influence to the apparatus and the substrate as well, the suitable semiconductor temperature at the time of executing the optical oxidation is in a range of 100 through 500° C., more preferably 200 through 350° C. In the first embodiment, the semiconductor temperature is set at 300° C.

In the optical oxidation apparatus according to the first embodiment, the pressures of both the atmosphere in the light source portion 2 and the atmosphere surrounding the surface of the substrate 6 is kept approximately equal to the atmospheric pressure, thus enabling the light transmittable window 4 to be thin. Accordingly, with this thin window, it becomes possible to lower the decrease in the effective light amount, to enlarge the scale of the substrate 6 to be processed, and to improve the oxidation speed. Furthermore, as each pressures of both the atmosphere in the light source portion 2 and the atmosphere surrounding the surface of the substrate 6 is approximately equal to the atmospheric pressure, there no need for an isolation wall to be provided. Still further, the power consumption can be made smaller with use of the low pressure-mercury vapor lamp.

(Second Embodiment)

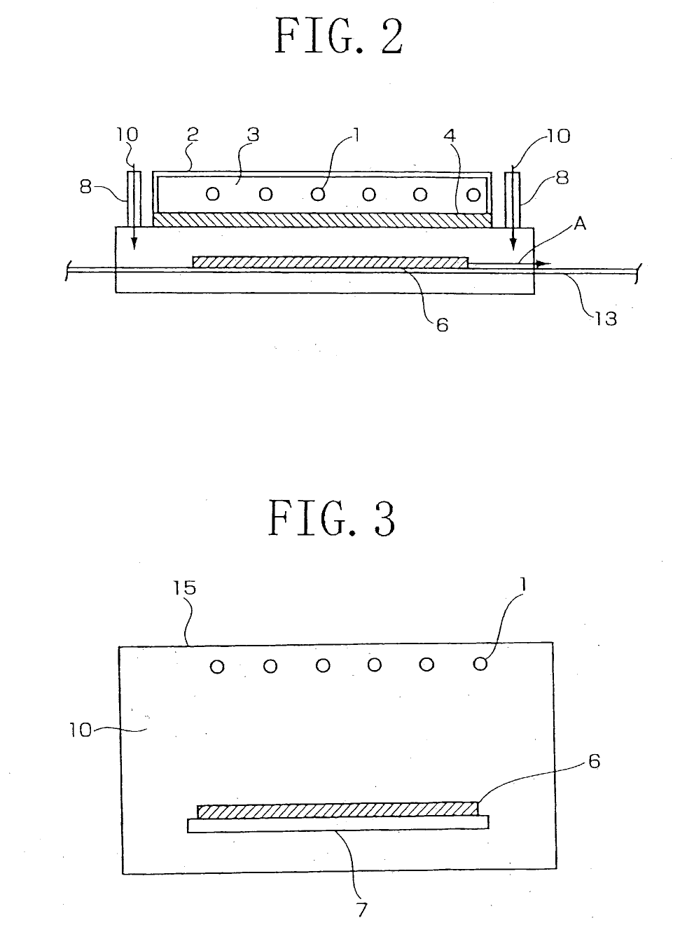

Referring to FIG. 2, a reference numeral 12 indicates a reaction chamber and 13 a belt for transferring a plurality of substrates 6 mounted thereon in the direction of the arrow A.

In this embodiment, the surface portion of the substrate 6 is connected with the outdoor air and the atmosphere surrounding the surface portion of the substrate 6 is keep at the atmospheric pressure by using the mixed gas 10 of O₂+N₂. The belt 13 is set up for mounting a plurality of substrates 6 thereon and transferring them under a light source portion 2.

In the first embodiment as described in the above, the light irradiation strength was 11 mW/cm² in the position of the substrate 6. However, a xenon excimer lamp now on market has the light irradiation strength of 60 mW/cm². On one hand, when the minimum thickness of the optically formed oxide film is about 1 nm, the boundary face characteristic can be effectively improved. Therefore, if using the xenon excimer lamp with the light irradiation strength of 60 mW/cm², a necessary oxide film can be formed within about one minute.

Accordingly, as shown in FIG. 2, if using a furnace which is provided with a belt 13 moving in the direction of the arrow A and is made open to the outdoor air, the oxide film can be optically formed on the surface of the substrate 6 by transferring the substrate through the reaction chamber (optical oxidation chamber) 12 by using the belt 13 moving in the direction of the arrow A. As the pressure of the atmosphere inside the light source portion 2 as well as surrounding the surface portion of the substrate 6 is kept at the atmospheric pressure, it is not necessary to prepare any isolation wall. The throughput in the manufacturing process is improved.

(Third Embodiment)

Referring to FIG. 3, a reference numeral 15 indicates a vacuum reaction chamber (vacuum tank).

In this embodiment, there are provided a means (gas exhaust port, not shown) for reducing the pressure of the atmosphere in the light source portion 2 as well as surrounding the surface portion of the substrate 6, and the other means (gas intake port, not shown) for returning the pressure of the atmosphere in the light source portion 2 as well as surrounding the surface portion of the substrate 6 to the atmospheric pressure. In this embodiment, as the pressure of the atmosphere is reduced, it becomes possible to prevent impurities from being mixed with the substrate 6.

In the previous embodiments 1 and 2, the surface portion of the substrate 6 where the chemical reaction takes place, is kept at an about atmospheric pressure. Contrary to this, in order to prevent impurities from being mixed with the dioxide film, there is a method for making the inside of the reaction chamber vacuum. In this case, in order to eliminate the pressure difference between the atmosphere of the light source portion 2 and that of the surface portion of the substrate 6, a plurality of xenon lamps 1 are directly set up inside the vacuum reaction chamber 15 as shown in FIG. 3. If setting up the vacuum reaction chamber like this, it becomes possible not only to eliminate the pressure difference between the atmosphere surrounding the xenon lamps 1 and that surrounding the surface portion of the substrate 6 but also to remove even the light transmittable window, regardless of any inside state of the vacuum reaction chamber, for instance such a state wherein the pressure is reduced, the reaction proceeds, and so forth. In this case, the oxide film is formed with the steps of first setting the substrate 6 in the reaction chamber 15; then exhausting the air in the reaction chamber to make it vacuum; introducing oxygen gas to the reaction chamber 15 to keep the pressure therein at about 70 Pa; and irradiating the substrate 6 by the light emitted from the xenon lamps 1.

(Fourth Embodiment)

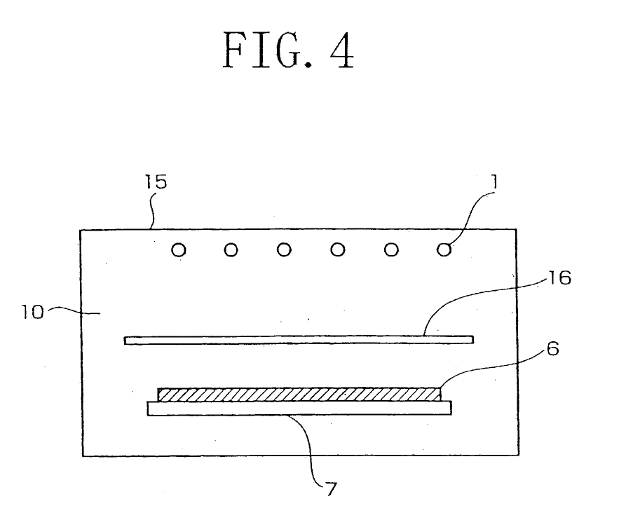

Referring to FIG. 4, a reference numeral 16 indicates a transparent plate provided between the light source portion 2 and the substrate 6.

In this embodiment, as the transparent plate 16 is provided between the light source portion 2 and the substrate 6, the atmosphere surrounding the light source portion 2 and that surrounding the surface of the substrate 6 are joined each other outside the transparent plate 16. Therefore, these two atmospheres are kept so as to have no pressure difference therebetween. In this embodiment, as the transparent plate 16 is provided between the light source 1 and the substrate 6, there is obtained such a effect that the impurities generated from the lamp electrode is prevented from being mixed with the substrate 6.

(Fifth Embodiment)

So far, the invention has been described by way of the first through fourth embodiments where the single crystalline silicon is used as a substrate. In this embodiment, there will be described a process for manufacturing a polycrystalline silicon thin film transistor (Poly-Si TFT) on a glass base plate, based on the results attained in the above four embodiments.

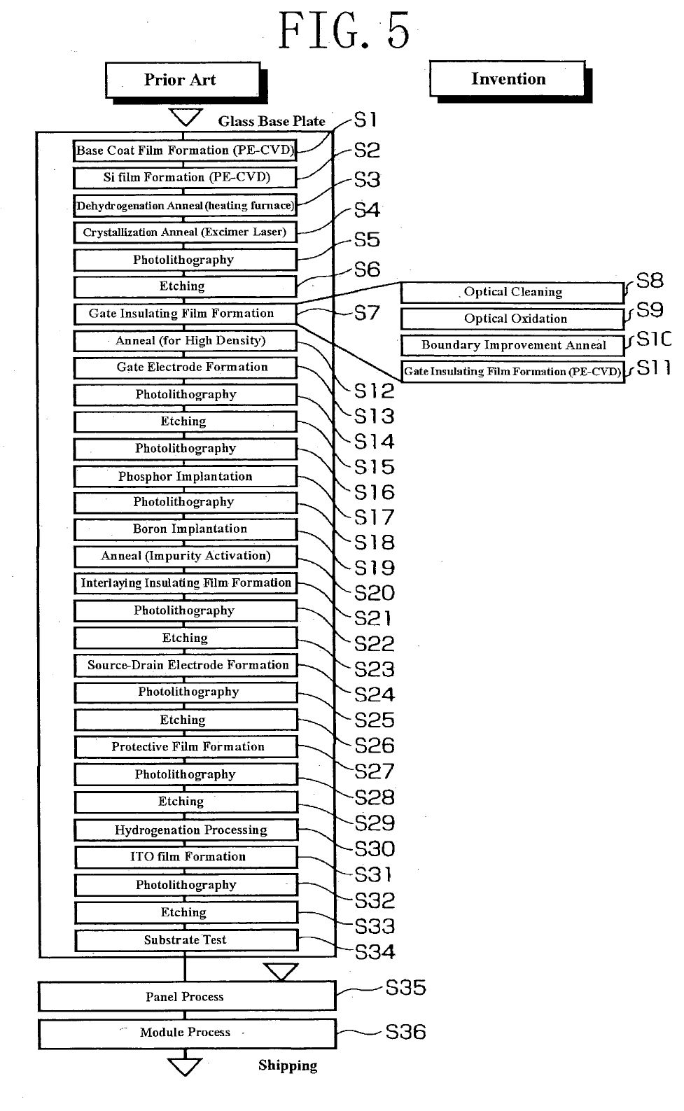

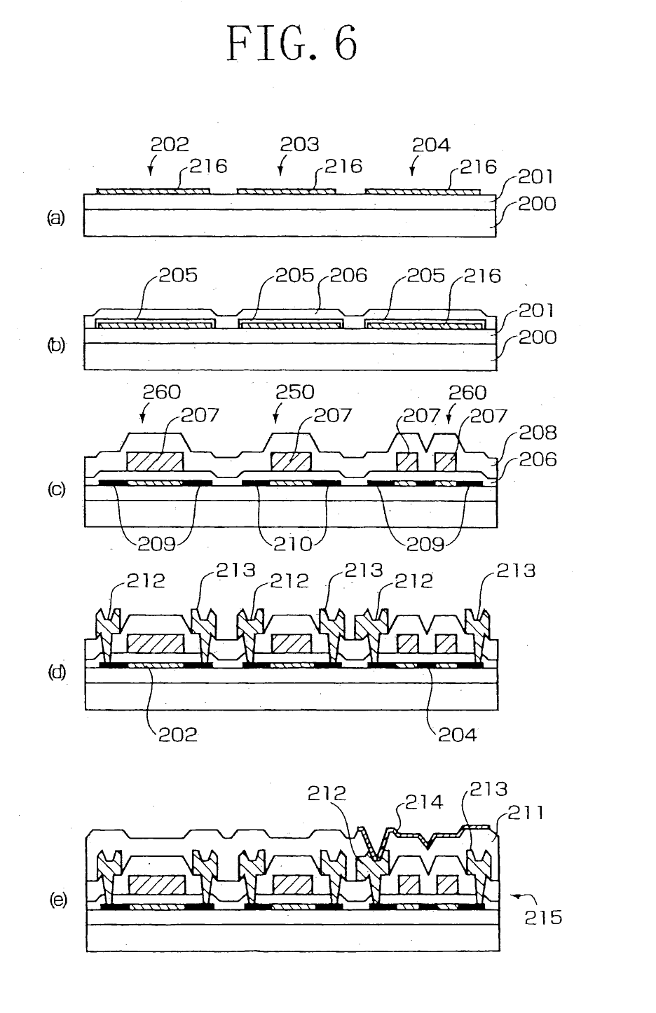

FIG. 5 is a flowchart showing a process for manufacturing an n-type or a p-type polycrystalline silicon thin film transistor (Poly-Si TFT) for use in a liquid crystal display device. FIGS. 6(a) through 6(e) are sectional views of each element (Poly-Si TFT′) obtained at each process of the flowchart as shown in FIG. 5.

A glass plate having a size of 320 nm×400 nm×1.1 nm is used as a glass base plate (200) (FIG. 6).

As shown in FIG. 6(a), a dioxide silicon film (SiO₂ film) having a thickness of 200 nm is formed as a base coat film 201 on a cleaned glass base plate 200 by the PE-CVD method (plasma CVD method) using TEOS gas (S1 in FIG. 5).

Then, an amorphous silicon film with a thickness of 50 nm is formed by the PE-CVD method using SiH₄ and H₂ gas (S2).

At this stage, this amorphous silicon film still includes hydrogen of 5 to 15 atomic percent. Therefore, if this film is directly irradiated by a laser beam, the above hydrogen is vaporized to abruptly expand its volume and the film is blown away eventually. For this, in order to cut the hydrogen bond as well as to drive out hydrogen, the glass base plate 200 having the amorphous film formed thereon is kept at a temperature of 350° C. or higher for about one hour (S3).

After that, the laser pulse (670 mJ/pulse) having a wavelength of 308 n emitted from the xenon chloride (XeCl) excimer laser beam source is formed to have a section of 8×130 mm through the optical system. Then, the laser pulse is applied to the amorphous silicon film formed on the glass base plate 200 to irradiate it with the strength of 360 mJ/cm². The amorphous silicon film absorbing the laser beam is melted to form a liquid phase. With the temperature drop of the liquid phase, it is solidified to form the poly-silicon crystal. As the laser beam is a pulse of 200 Hz, the process of melting and solidifying the amorphous silicon film is completed for the duration of one pulse. Therefore, this process is repeated by laser irradiation by every pulse. Accordingly, if executing this laser irradiation while the supporting glass base plate 200 is moved, it becomes possible to crystallize the entirety of the amorphous silicon film having a large area. In this case, the laser irradiation is executed such that respective irradiation areas overlap with each other at a rate of 95% through 97.5% in order to avoid the variation in the characteristic of the polycrystalline silicon film, in other words, of the resultant TFT (S4)

This polycrystalline silicon layer is then processed according to the patterning carred out executed in the photolithography step (S5) as well as in the etching step (S6) to form a plurality of island shaped polycrystalline silicon layers 216 corresponding to a source, a channel, and a drain, thereby forming an n-channel TFT area 202, a p-channel TFT area 203, and a pixel portion TFT area 204 (FIG. 6(a))

Then, the invention is applied to the formation of the boundary and insulating film (S7) which is the most significant step in the manufacturing process of TFT.

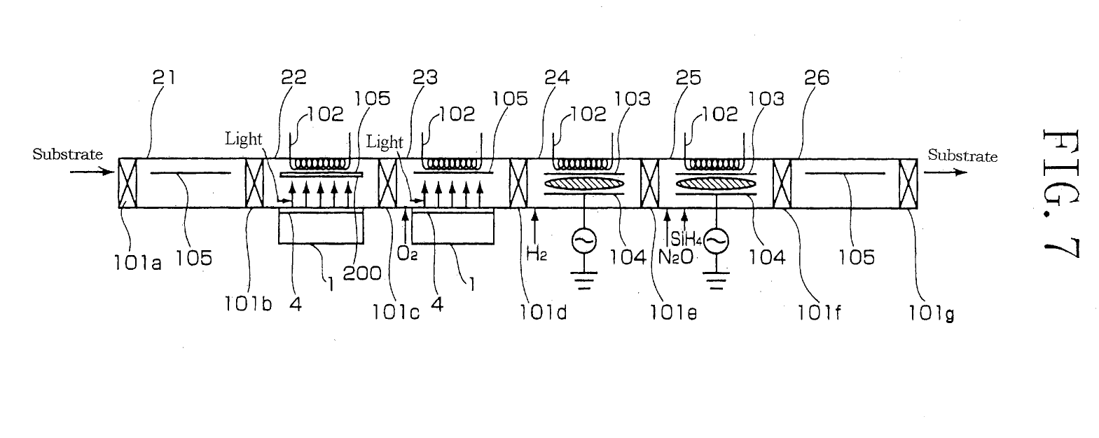

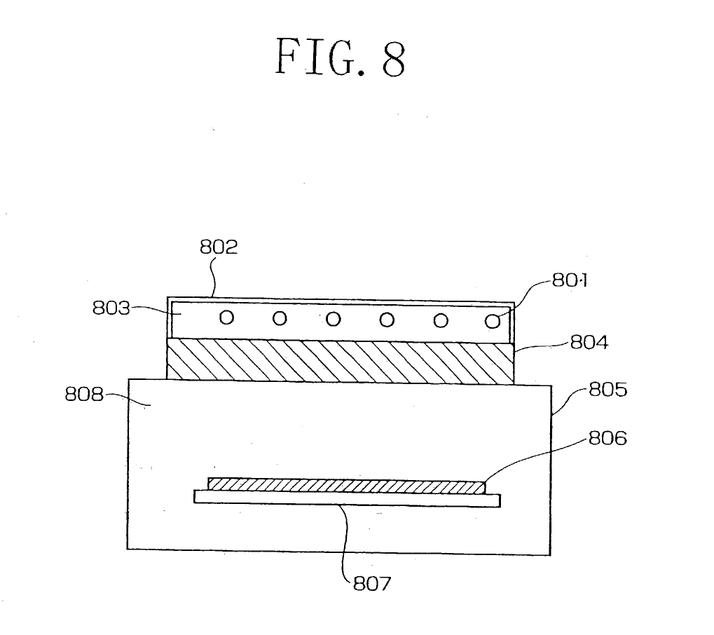

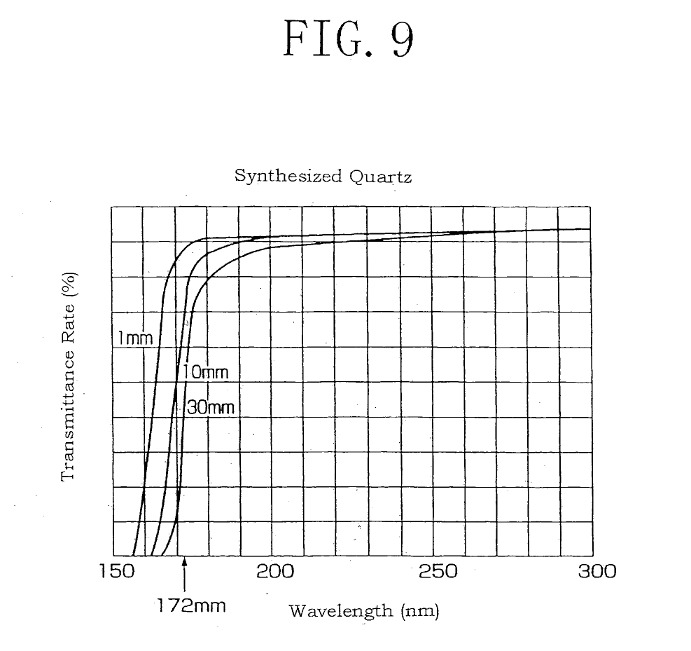

FIG. 7 is a schematic sectional view showing apparatus for forming an insulating film of the complex type according to the invention, which is made up of a thin film deposition system of the single wafer processing type using the optical oxidation method and a thin film deposition system using the CVD method.

In this figure, a reference numeral 1 indicates the xenon excimer lamp, 4 the transparent window made of synthesized quartz, 21 a loading chamber, 22 the optical cleaning chamber, 23 the optical oxidation chamber, 24 the hydrogen plasma chamber, 25 the film formation chamber, 26 an unloading chamber, 200 the glass base plate, 101a through 101g a gate valve, 102 a heater, 103 a cathode electrode, 104 an anode electrode, and 105 a base supporting glass base plate, respectively.

The apparatus shown in FIG. 7 has a plurality of reaction chambers including the optical oxidation chamber 23 as the first reaction chamber for accommodating the glass base plate 200 and forming the first insulating film by using the optical oxidation method and the film formation chamber 25 as the second reaction chamber for accommodating the glass base plate 200 and forming the second insulating film on the first insulating film by using the deposition method, and a plurality of gate valves 101a through 101g as means for transferring the glass base plate 200 between the above plural reaction chambers without exposing the substrate to the outdoor air.

At first, the gate valve 101a is opened. After introducing the glass base plate 200 having island shaped polycrystalline silicon layers 216 on the above base coating film 201 (FIG. 6(a)) to the loading chamber 21 (FIG. 7), the gate valve 101a is closed and the loading chamber 21 is exhausted to make it vacuous. In the next, the gate valve 101b is opened. After the glass base plate 200 is transferred to the optical cleaning chamber 22, the gate valve 10b is closed. After setting the glass base plate 200 on the base 105 heated at a temperature of 350° C., the silicon surface (surface of the island shaped poly crystalline silicon layer 216) is irradiated by the light having a wavelength of 172 nm from the xenon excimer lamp 1 as the light source through the light transmittable window 4, thereby cleaning the silicon surface (S8).

In this reaction chamber i.e. the optical cleaning chamber 22, there is provided a penetrating portion for keeping the pressure of the atmosphere surrounding the xenon excimer lamp 1 and the grass base plate 200 at the even level. In this case, it is possible to use the low-pressure mercury lamp as a light source, but the xenon excimer lamp 1 shows higher cleaning effect than the low-pressure mercury lamp. The light irradiation strength is 60 mW/cm² at the point immediately after having passed through the window 4 while the distance from the window 4 to the silicon surface is kept at a distance of 25 mm.

Then, the gate valve 101c is opened to transfer the glass base plate 200 to the optical oxidation chamber 23 (the first reaction chamber for forming the first insulating film), and is closed after having finished this transfer. In the optical oxidation chamber, there is provided a penetrating portion for keeping the pressure of the atmosphere surrounding respective portions of the xenon excimer lamp 1 and the grass base plate 200 as well at the same level. After setting the glass base plate 200 (not shown) on the base 105 heated at 350° C., oxygen gas is introduced to the optical oxidation chamber 23 such that the inside pressure of the chamber is kept at 70 Pa. Furthermore, with the light having a wavelength of 172 nm emitted from the xenon excimer lamp 1, the introduced oxygen gas is effectively resolved into the oxygen atom active species of very high reactivity, by which the surface of the island shaped polycrystalline silicon layer 216 is oxidized, thereby the optical oxide film made of SiO₂ being formed. This optical oxide film will perform as the gate insulating film 205 (the first insulating film in FIG. 6(b)) later. In this instance, the first gate film (the first insulating film) was grown to the thickness of about 3 nm for 3 minutes (S9).

Then, in order to execute the anneal processing for boundary improvement, the gate valve 101d is opened to transfer the glass base plate 200 to the hydrogen plasma chamber 24 and is closed after finishing this transfer. In the hydrogen plasma chamber 24, the temperature of the base 105, the flow rate of H₂ gas, and the pressure of H₂ gas are kept at 350° C., at 1000 sccm, and 173 Pa (1.3 Torr), respectively, and the hydrogen plasma processing is applied to the optical oxide film for 3 minutes under the condition that the pressure inside the hydrogen plasma chamber is 80 Pa (0.6 Torr) and the power of RF source is 450 W (S10).

In the next, the gate valve 101e is opened to transfer the glass base plate 200 to the film formation chamber 25 (the second reaction chamber for forming the second insulating film) and is closed after completing this transfer. In the film formation chamber 25, the temperature of the base 105, the flow rate of SiH₄ gas, and the flow rate of N₂O gas are kept at 350° C., at 30 sccm, and 6000 sccm, respectively, and the second gate insulating film 206 (the second insulating film) made of SiO₂ is formed by the plasma CVD method under the condition that the pressure inside the film formation chamber 25 is 267 Pa (2 Torr) and the power of RF source is 450 W (S11).

Then, the gate valve 101f is opened to transfer the glass base plate 200 to the unloading 26 and is closed after completing this transfer. Next, the gate valve 101g is opened to take out the glass base plate 200 (FIG. 6(b)).

In the processing using the apparatus for forming the insulating film described as the 5th embodiment of the invention referring to FIG. 7, all the steps of optical cleaning (S8), optical oxidation (S9), annealing for boundary improvement (S10), and forming the first gate insulating film 205 by using the plasma CVD method can be continuously carried out in the vacuum, without dropping the productivity. Accordingly, it becomes possible to form a high quality boundary between the semiconductor (island shaped polycrystalline silicon layer 216) and the first gate insulating film and also to speedily form the thick and practically usable insulating film.

After this, the Poly-Si TFT is formed according to the same steps as the prior art ones.

That is, the glass base plate 200 is first annealed at a temperature of 350° C. in nitrogen gas for 2 hours, thereby raising the density of the first gate insulating film 205 made of SiO₂ (S12). With this high density process, the density of the SiO₂ film is raised, thus the leakage current as well as the breakdown voltage being improved in the preferable direction, that is, decreasing the leakage current but increasing the breakdown voltage.

Then, after forming titanium (Ti) film having a thickness of 100 nm by means of the spattering method, Ti being used as a barrier metal, an aluminum (Al) film having a thickness of 400 nm is formed in the same way by using the spattering method (S13). This metal layer made of Al is processed according to the patterning carried out in the photolithography step method (S14) and in the etching step (S15), thereby the gate electrode 207 being formed as shown in FIG. 6(c).

Next, the photo resist (not shown) is applied to only the p-channel TFT 250 to cover it in the photolithography step (S16) and then, the phosphor ion is doped in the n+ source-drain contact portion 209 of the n-channel TFT 260 by way of the ion implantation with the condition of 80 KeV and 6×10¹⁵/cm² (S17). At this time, the gate electrode 207 works as a protective mask against ions. As to the ion doping method, it is not limited to the ion implantation method; the plasma doping method is usable, for instance.

Furthermore, as shown in FIG. 6(c), two n-channel TFT's 260 of which one includes the n-channel TFT region 202 and the other includes the pixel portion TFT region 204 are commonly covered with the photo resist in the photolithography step (S18) and then, boron ion is implanted in the p+source-drain contact portion 210 of the p-channel TFT 250 (FIG. 6(c)) including the p-channel TFT region 203 (FIG. 6(a)) by way of the ion implantation with the condition of 60 KeV and 1×10¹⁶/cm² (S19). In this case, the gate electrode 207 works as a protective mask against ions.

Then, the glass base plate 200 is annealed at a temperature of 350° C. for 2 hours, thereby the ion doped phosphor and boron being activated (S20). After this, as shown in FIG. 6(c), an interlaying insulating film 208 made of SiO₂ is formed by using the plasma CVD method using TEOS gas (S21).

In the next, as shown in FIG. 6(d), the contact holes to the n+ source-drain contact portion 209 and p+ source-drain contact portion 210 as well are formed according t the patterning carried out in the photolithography step (S22) as well as in the etching step (S23). Then, after forming a titanium (Ti) film having a thickness of 100 nm by using the spattering method, Ti being used as a barrier metal (not shown), an aluminum (Al) film having a thickness of 400 nm is formed in the same manner by using the spattering method (S24). After this, the source electrode 213 and the drain electrode 212 are formed according to the patterning carried out in the photolithography step (S25) and the etching step (S26).

Furthermore, as shown in FIG. 6(e), a protective film 211 made of SiO² film is formed to the thickness of 350 nm by means of thee plasma CVD (S27) and then, the hole for connecting with a pixel electrode 214 (descried later) made of indium tin oxides (ITO) is formed in the drain portion 212 of the n-channel TFT 260 (FIG. 6(c)) including the pixel portion TFT 204 region (FIG. 6(a)), according to the patterning carried out in the photolithography step (S28) as well as in the etching step (S29).

After the above processing, in the multi-chamber spattering apparatus of the single water processing type, the hydrogen plasma processing is executed for 3 minutes under the condition that the glass base temperature is 350° C., the flow rate of H₂ gas is 1000 sccm, the gas pressure is 173 (1.3 Torr), and the RF source power is 450 W (S30).

Then, the glass base plate 200 is transferred to another other reaction chamber and the ITO film is formed to a thickness of 150 nm (S31). The ITO film is formed as the pixel electrode 214 according to the patterning carried out in the photolithography step (S32) as well as in the etching step (S33), thereby the TFT substrate 215 being completed (FIG. 6(e)) and being ready for receiving the test (S34).

After applying polyimide to the TFT substrate (glass base plate) 215 as well as to another glass base plate having a color filter formed on one side thereof (not shown) such that the TFT array side of the former and the color filter side of the latter are coated with polyimide and then, rubbing the cured polyimide surfaces, these glass base plates are put together such that two cured polyimide surfaces oppose to each other with a predetermined space therebetween. Then, that which is put together is divided into respective panels having a desired size.

These panels are put in a vacuum tank while the liquid crystal filling port of the panel is put in the liquid crystal contained in a shallow vessel. The air being introduced into the vacuum tank, the liquid crystal is pushed into the panel through the filling port by the pressure of the air to fill the panel. Then, the filling port is sealed with a resin, thereby the liquid crystal panel being completed (S35).

In the next, the polarizer is put on both sides of the liquid crystal panel. Furthermore, peripheral circuits, a backlight, a bezel, and so forth are fitted on the liquid crystal panel, thereby a liquid crystal module being completed (S36).

This liquid crystal module can be used in personal computers, monitors, TV sets, portable terminals, and forth.

In case of the prior art TFT wherein no optical oxide layer (optical oxide film) is formed and the SiO2 film is formed by the plasma CVD method, the threshold voltage of the TFT is 1.9±0.8 V. In case of the TFT according to the fifth embodiment, its threshold voltage is reduced to 1.5±0.6 V due to the improved characteristic of the boundary between the silicon oxide film and the polycrystalline silicon (island shaped polycrystalline silicon layer 216) and the improved characteristic of the insulating film bulk. With reduction in the deviation of the threshold voltage, the rate of acceptable products in the manufacturing is improved to a great extent. Furthermore, as the driving voltage can be made lower, 10% reduction of the power consumption becomes possible. Still further, as the clean boundary can be formed between the silicon oxide film and the polycrystalline silicon by using the optical cleaning and the optical oxidation, it becomes possible to prevent the contamination by sodium ion or the like. Still further, as the threshold voltage is less varied, the reliability is highly improved.

While some embodiments of the invention have been concretely described, the invention is not limited to such embodiments. Needless to say, it will be apparent that various changes and modifications are possible in the scope without departing from the gist of the invention.

For instance, the invention is applicable to various materials. That is, in the first through fourth embodiments as discussed in the above, the invention is applied to the single crystalline silicon surface while, in the fifth embodiment, the invention is applied to the polycrystalline silicon layer formed on the glass base plate. Accordingly, the invention is applicable to the single crystalline silicon layer and the polycrystalline silicon layer formed on various base plates such as a plastic base plate.

Furthermore, the invention is widely applicable to various semiconductor devices, that is, the TFT, the single crystalline silicon MOS type transistor, and so forth. Still further, in the optical oxidation capable of forming a good quality boundary between the semiconductor and the insulating film, as the oxidation speed is so fast that the invention can be applied to apparatus for manufacturing an insulating film capable of handling the large scale glass base plate.

As has been discussed in the above, according to the invention, there is provided apparatus for forming an insulating film, which is able to reduce the decrease in the light amount due to the light transmittable window, to process the large scale base plate, and to improve the oxidation speed.

What is claimed is:

1. Apparatus for forming an insulating film on a semiconductor surface by oxidizing said semiconductor surface by means of oxygen atom active species which are generated when irradiating an atmosphere including at least oxygen with the light emitted from a light source,
wherein there is provided a means for keeping the pressure of the atmosphere surrounding said light source and that of the atmosphere surrounding said semiconductor surface portion approximately equal to each other.

2. Apparatus as claimed in claim 1, wherein there is provided a light transmittable window allowing the light emitted from said light source to pass it through between said light source and said semiconductor surface portion,
the pressure of the atmosphere surrounding said light source is made to be at an atmospheric pressure by a gas not absorbing the light emitted from the light source, and
there is provided a means for making the pressure of the atmosphere surrounding said semiconductor surface portion be at the atmospheric pressure by a mixed gas including at least oxygen and said gas not absorbing the light emitted from the light source.

3. Apparatus as claimed in claim 2, wherein the atmosphere surrounding said semiconductor surface portion communicates with the outdoor air and said atmosphere surrounding said semiconductor surface portion is kept at an atmospheric pressure by using said mixed gas.

4. Apparatus as claimed in claim 3, wherein there is provided a means for transferring a plurality of substrates under the said light source.

5. Apparatus as claimed in claim 1, wherein there are provided means for reducing both pressures of atmospheres surrounding said light source and said semiconductor surface portion without making difference pressures between them, and
means for returning both pressures of atmospheres surrounding said light source and said semiconductor surface portion to the atmospheric pressure without making difference pressures between them.

6. Apparatus as claimed in claim 5, wherein there is provided a transparent plate between said light source and said semiconductor surface portion, said transparent plate is held not so as to make any pressure difference between the both atmospheres surrounding said light source and said semiconductor surface portion.

7. Apparatus as claimed in claim 1, wherein said light source is formed of a low pressure-mercury lamp.

8. Apparatus as claimed in claim 1, wherein said light source is formed of a xenon excimer lamp.

9. Apparatus as claimed in claim 1, wherein there are provide a plurality of reaction chambers including a reaction chamber for forming the first insulating film by making the pressure of the atmosphere surrounding said light source and that of the atmosphere surrounding the semiconductor surface portion approximately equal to each other and the second reaction chamber forming the second insulating film on said first insulating film by using a deposition method, and a means for transferring said substrate between said plural reaction chambers without exposing said substrate to the outdoor air.
